(19) United States
(12) Patent Application Publication
(10) Pub. No.: US 2024/0250129 A1
(43) Pub. Date: Jul. 25, 2024

(54) SiC SEMICONDUCTOR DEVICE

(71) Applicant: MITSUBOSHI DIAMOND INDUSTRIAL CO., LTD., Settsu city (JP)

(72) Inventors: Mitsuru KITAICHI, Settsu city (JP); Yoshiyuki ASAI, Settsu city (JP); Masakazu TAKEDA, Settsu city (JP)

(21) Appl. No.: 18/627,879

(22) Filed: Apr. 5, 2024

Related U.S. Application Data
(63) Continuation of application No. PCT/JP2022/036049, filed on Sep. 28, 2022.

(30) Foreign Application Priority Data
Oct. 8, 2021 (JP) 2021-166199

(51) Int. Cl. H01L 29/34; H01L 21/78; H01L 29/16

(52) U.S. Cl. CPC H01L 29/34; H01L 21/78; H01L 29/1608

(57) ABSTRACT

A SiC semiconductor device including a SiC semiconductor layer composed of SiC single crystal. The SiC semiconductor layer comprising a mounted surface on which an element is mounted, a non-mounted surface opposed to the mounted surface, and a side surface connecting the mounted surface to the non-mounted surface, wherein the side surface is on a cleavage plane of the SiC single crystal.

### CROSS REFERENCE TO RELATED APPLICATIONS

This application is a continuation application of International Application No. PCT/JP2022/036049, filed on Sep. 28, 2022, which claims the benefit of priority to Japanese Patent Application No. 2021-166199, filed on Oct. 8, 2021. The entire contents of each of these applications are hereby incorporated herein by reference.

### BACKGROUND OF THE INVENTION

### 1. Field of the Invention

The present invention relates to a SiC (silicon carbide) semiconductor device.

### 2. Description of the Related Art

Generally, a manufacturing process of a semiconductor device comprises a step of producing a semiconductor wafer, a step of forming a plurality of semiconductor elements (semiconductor electronic circuitries) on the semiconductor wafer, a step of dividing the semiconductor wafer with the semiconductor elements formed thereon into a plurality of semiconductor chips (semiconductor devices), and a step of assembling a plurality of the semiconductor devices using the semiconductor chips.

Examples of the step of dividing the semiconductor wafer include blade dicing, which is the most typical one, and another disclosed in International Application Publication No. WO 2019/082724 A1 (referred to as Patent Document 1). Examples of techniques concerning a structure of the semiconductor chip are disclosed in Patent Document 2 and Patent Document 3.

Examples of the step of dividing the semiconductor wafer include blade dicing, which is the most typical one, and another disclosed in International Application Publication No. WO 2019/082724 A1 (referred to as Patent Document 1). Examples of techniques concerning a structure of the semiconductor chip are disclosed in Japanese Unexamined Patent Application Publication No. 2011-249384 (referred to as Patent Document 2) and Japanese Unexamined Patent Application Publication No. 2020-036048 (referred to as Patent Document 3).

Patent Document 1 discloses scribing a metal-film surface of a substrate having a metal film thereon and breaking the substrate having the metal film by means of a breaking bar.

Patent Document 2 discloses forming an InGaAlN-based layered structure on a main surface of a substrate to reduce a crystal defect density on the main surface relative to the crystal defect density on a peripheral edge face of the substrate.

Patent Document 3 discloses a SiC semiconductor device (chip) having a side surface inclined at an angle less than an off-angle with respect to an element-formed surface (main surface) of the SiC semiconductor device (chip).

A semiconductor chip is produced by blade-dicing a semiconductor wafer, of which side surfaces are formed by grinding (removal of material) with use of a dicing blade. This may cause crystal defects on the side surfaces and a current leakage through the crystal defects. Therefore, it is necessary to broaden a peripheral region (depletion layer), which is disposed between the side surfaces and the element-formed region on a main surface of the semiconductor chip, for enhanced withstanding voltage to avoid the current leakage. This requires a larger size or area of the semiconductor chip.

Also, chipping and microcracking are likely caused on the edges of the semiconductor chip produced by the blade dicing process, of which sizes are substantial as several tens of micrometers. As the degree of integration and performance of the semiconductor chips are enhanced, an amount of heat generated during operation of the semiconductor chips tends to increase, and such chipping and microcracking may cause thermal stress cracking of the semiconductor chips (see the left images in FIG. 6).

The SiC semiconductor wafers for producing power semiconductor devices may be formed of 4H (Hexagonal)-SiC crystal (with an off-angle of 4°), of which cleavage plane is inclined away from a plane orthogonal to the main surfaces of the SiC semiconductor wafers. The side surfaces of the semiconductor chip produced by the blade dicing process are formed along a plane orthogonal to the top surface (mounted surface), and therefore deviate from the cleavage plane. Specifically, with the blade dicing process, the semiconductor wafer is divided or dug in the direction perpendicular to the top surface irrespective of the crystal orientation of the cleavage plane, chipping and microcracking are inevitable on the side surfaces of the semiconductor chips. Therefore, the semiconductor chips obtained by the blade dicing process are likely to be damaged by heat, stress or the like generated during operation, and thus improvement on the reliability has been desired.

As described above, there is a need for the semiconductor chip having less chipping, microcracking and crystal defects on the side surfaces thereof to suppress the cracking of the semiconductor chip caused by heat or the like generated during operation thereof.

While the side surfaces of the semiconductor chip obtained by the blade dicing process are planes other than cleavage planes, which causes many crystal defects thereon, the present inventors have thought that the side surfaces of the semiconductor chip are formed in the cleavage planes to reduce crystal defects and irregularities on the side surfaces.

Patent Document 1 does not disclose a SiC semiconductor device having side surfaces formed in the crystal planes, i.e., cleavage planes, and does not disclose reducing the crystal defects on the side surfaces. Moreover, Patent Document 1 does not disclose a SiC semiconductor chip in which a pair of opposed side surfaces (side surfaces perpendicular to an orientation flat) are each formed to include a plane perpendicular or nearly perpendicular to a main surface (top surface) and a plane inclined with respect to the main surface.

Patent Document 2 discloses the SiC semiconductor chip in which the density of crystal defects on a main surface (top surface) is reduced but fails to disclose reducing the density of crystal defects on the side surfaces.

Patent Document 3 also fails to disclose a SiC semiconductor chip of which side surfaces are perpendicular or nearly perpendicular to a main surface (top surface) and inclined with respect to the main surface.

### SUMMARY OF THE INVENTION

Specifically, according to the findings of the present inventors, in order to solve the problems due to the crystal defects causing current leakage after the SiC semiconductor chip is mounted, and the problems due to the chipping or the like causing cracking when heat is generated during operation, it is desirable that, regardless of whether the mother semiconductor wafer has the off-angle, the side surfaces of the SiC semiconductor chip preserve their crystal structure, and it is preferable that the side surfaces are smooth.

In view of the foregoing problems, the preferred embodiments of the present invention provide a SiC semiconductor chip in which, regardless of whether the SiC semiconductor wafer has the off-angle, cleavability is utilized during division to expose divided surfaces in the crystal planes, to preserve the crystal structure on the side surfaces and to reduce the chipping and microcracking, thereby achieving high bending strength and high reliability of the SiC semiconductor chip.

A SiC semiconductor device includes a SiC semiconductor layer composed of SiC single crystal, in which the SiC semiconductor layer comprises a mounted surface on which an element is mounted, a non-mounted surface opposed to the mounted surface, and a side surface connecting the mounted surface to the non-mounted surface, wherein the side surface is on a crystal plane (cleavage plane) of the SiC single crystal.

The SiC semiconductor layer may include a SiC epitaxial layer or the like formed on the mounted surface and a metal layer or the like formed on the non-mounted surface.

The amount (area ratio) of an area having crystal defects detected over the side surface of the SiC semiconductor layer by means of an EBSD (Electron Backscatter Diffraction Pattern) analysis is 10% or less, preferably 5% or less. The amount (area ratio) of the area having crystal defects can be measured, for example, by EBSD (Electron Back Scattered Diffraction Pattern) technique.

In a middle portion of the side surface along a thickness direction of the SiC semiconductor layer, each of a vertical surface roughness (maximum height Rz, vertical) along the thickness direction and a horizontal surface roughness (maximum height Rz, horizontal) along a horizontal direction orthogonal to the thickness direction may be 5 μm or less.

A horizontal arithmetic mean surface roughness (Ra, horizontal) along the horizontal direction may be equal to or more than a vertical arithmetic mean surface roughness (Ra, vertical) along the horizontal direction to satisfy following formula [1].

$$Ra [ horizontal direction ] \geq Ra [ vertical direction ] \qquad [ 1 ]$$

The SiC semiconductor device may be produced by forming a scribe line on a SiC semiconductor wafer using a scribing tool and then applying an external force along the scribe line to divide the SiC semiconductor wafer.

The side surface of the SiC semiconductor layer may include a vertical crack surface originating from a vertical crack generated by forming the scribe line, and a divided surface formed by applying the external force along the scribe line to divide the SiC semiconductor wafer.

On the side surface of the SiC semiconductor layer, the vertical crack surface may be adjacent to the mounted surface, and the divided surface may be adjacent to the non-mounted surface, or alternatively, the vertical crack surface may be adjacent to the non-mounted surface, and the divided surface is adjacent to the mounted surface.

A thickness of which the vertical crack surface extends along a thickness direction of the SiC semiconductor layer may be 20% or less of a thickness of the SiC semiconductor layer.

An arithmetic mean roughness (Ra, vertical crack surface, horizontal) of the vertical crack surface in a direction orthogonal to a thickness direction may be equal to or less than an arithmetic mean roughness (Ra, divided surface, horizontal) of the divided surface in the direction orthogonal to the thickness direction to satisfy following formula [2].

$$Ra [ vertical crack surface , horizontal ] \leq Ra [ divided surface , horizontal ] \qquad [ 2 ]$$

The surface roughness of the vertical crack surface and the surface roughness of the divided surface can be optimized by selecting, for example, processing conditions during division (such as specifications of the scribing tool (the outer diameter of a scribing wheel, the angle of its cutting edge, micromachining on the cutting edge, or the like), a scribing load, a scanning speed of the scribing tool, specifications of a breaking bar (the angle of its cutting edge and a tip shape of the cutting edge), a gap between receiving blades, a hardness of a table, a breaking load (pressing amount), and a pressing down speed of the breaking bar).

A SiC semiconductor device according to the invention includes a SiC semiconductor layer composed of SiC single crystal, in which the SiC semiconductor layer comprises a mounted surface on which an element is mounted, a non-mounted surface opposed to the mounted surface, a first pair of side surfaces connecting the mounted surface to the non-mounted surface and opposing to each other, each of the first pair of side surfaces being on a cleavage plane of the SiC single crystal, and a second pair of side surfaces connecting the mounted surface to the non-mounted surface and opposing to each other, wherein each of the second pair of side surfaces includes first and second side regions, one of the first and second side regions being adjacent to the mounted surface and another one of the first and second side regions being adjacent to the non-mounted surface, and the first side region is inclined to the second side region by a predetermined angle.

An angle (A) between one of the non-mounted surface or the mounted surface and the second side region adjacent to the one of the non-mounted surface or the mounted surface may be closer to 90° than another angle (B) between another one of the mounted surface or the non-mounted surface and the first side region adjacent to the another one of the mounted surface or the non-mounted surface. Alternatively, an angle (B) between one of the non-mounted surface or the mounted surface and the first side region adjacent to the one of the non-mounted surface or the mounted surface may be closer to 90° than another angle (A) between another one of the mounted surface or the non-mounted surface and the second side region adjacent to the another one of the mounted surface or the non-mounted surface.

One of the second pair of side surfaces may have a ridge line where the first side region meets the second side region, and another one of the second pair of side surfaces may have a valley line where the first side region meets the second side region.

The predetermined angle (C) between the first side region and the second side region may be within the range of 0.1° to 10°.

The second side region may be inclined by a given angle (A) within the range of 80° to 100°, to either one of the mounted surface or the non-mounted surface which is adjacent to the second side region.

The first side region may be on a {11-20} plane, i.e., a (11-20) plane or a (-1-120) plane of the SiC single crystal.

The SiC semiconductor device may be produced by forming a scribe line on a SiC semiconductor wafer using a scribing tool and then applying an external force along the scribe line to divide the SiC semiconductor wafer.

The second side region may originate from a vertical crack generated by forming the scribe line, and the first side region may be a divided surface formed by applying the external force along the scribe line to divide the SiC semiconductor wafer.

The first side region may be adjacent to the mounted surface, and the second side region is adjacent to the non-mounted surface, or the first side region may be adjacent to the non-mounted surface, and the second side region is adjacent to the mounted surface.

A thickness of which the second side region extends along a thickness direction of the SiC semiconductor layer may be 20% or less of a thickness of the SiC semiconductor layer.

An angle (A) between one of the non-mounted surface or the mounted surface and the second side region adjacent to the one of the non-mounted surface or the mounted surface is closer to 90° than another angle (B) between another one of the mounted surface or the non-mounted surface and the first side region adjacent to the another one of the mounted surface or the non-mounted surface.

An angle (B) between one of the non-mounted surface or the mounted surface and the first side region adjacent to the one of the non-mounted surface or the mounted surface may be closer to 90° than another angle (A) between another one of the mounted surface or the non-mounted surface and the second side region adjacent to the another one of the mounted surface or the non-mounted surface.

The above and other elements, features, steps, characteristics and advantages of the present invention will become more apparent from the following detailed description of the example embodiments with reference to the attached drawings.

### BRIEF DESCRIPTION OF THE DRAWINGS

A more complete appreciation of example embodiments of the present invention and many of the attendant advantages thereof will be readily obtained as the same becomes better understood by reference to the following detailed description when considered in connection with the accompanying drawings described below.

FIG. 1 is schematic cross-sectional and perspective views of the SiC semiconductor device of the first preferred embodiment.

FIG. 2 are photographs showing analysis results on a crystal plane of a SiC semiconductor device divided by blade dicing (conventional Blade process) and the analysis results on a crystal plane of the SiC semiconductor device of the preferred embodiment (SnB).

FIG. 3 is a graph comparing the number of the SiC semiconductor devices obtained.

FIG. 4 is a graph comparing the bending strengths of the SiC semiconductor devices.

FIG. 5 is schematic cross-sectional and perspective views of the SiC semiconductor device (4H-SiC single crystal) of the second preferred embodiment.

FIG. 6 are photographs comparing whether the SiC semiconductor devices have chippings depending on the conventional Blade process and SnB process for producing thereof.

FIG. 7 are photographs comparing images of the divided surfaces (of the side surface) parallel and orthogonal to an orientation flat (OF).

FIG. 8 is a graph comparing the bending strengths of SiC semiconductor devices.

FIG. 9 is a schematic perspective view of the SiC semiconductor device.

### DETAILED DESCRIPTION OF THE EXAMPLE EMBODIMENTS

The example embodiments will now be described with reference to the accompanying drawings, wherein like reference numerals designate corresponding or identical elements throughout the various drawings. The drawings are to be viewed in an orientation in which the reference numerals are viewed correctly.

Example embodiments of the present invention will be described below with reference to the drawings.

While a 4H (Hexagonal)-SiC single crystal is used as a hexagonal SiC single crystal in the preferred embodiments of the present invention, the present invention is applicable to the hexagonal SiC single crystal such as a 2H-SiC single crystal and a 6H-SiC single crystal. The present invention is suitably adapted for manufacturing SiC power devices, SiC high-frequency devices, and semiconductor devices using the other compound semiconductors.

First, a SiC semiconductor wafer 11 will be described. The SiC semiconductor wafer 11 may be referred to simply as the wafer 11, and the SiC semiconductor device 1 may be referred to simply as the chip 1.

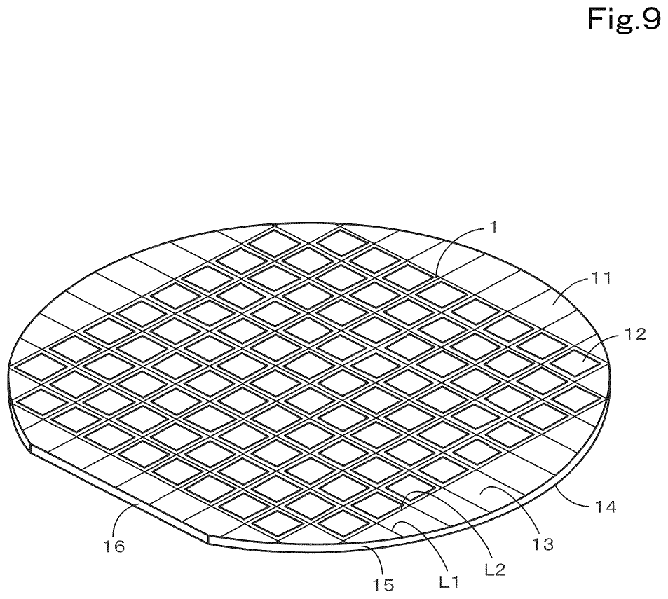

FIG. 9 schematically shows an example of the wafer 11. The wafer 11 is a base material from which a plurality of the chips 1 of the present invention are produced. In the preferred embodiments, the wafer 11 includes a semiconductor layer composed of 4H-SiC single crystal.

The wafer 11 is shaped in a disk and has a first wafer main surface 13 on one hand, a second wafer main surface 14 on the other hand, and a wafer peripheral side 15 that connects the first wafer main surface 13 to the second wafer main surface 14. A plurality of element-formed regions 12 each having an element formed thereon and corresponding to a chip 1 are mounted on the first wafer main surface 13. A cut-out portion is formed on the wafer peripheral side 15. The cut-out portion is referred to as an orientation flat (OF), which is a mark indicating the crystal orientation of the SiC single crystal. For example, one or two orientation flats may be provided. A plurality of chips 1 are diced by dividing the wafer 11.

### First Embodiment

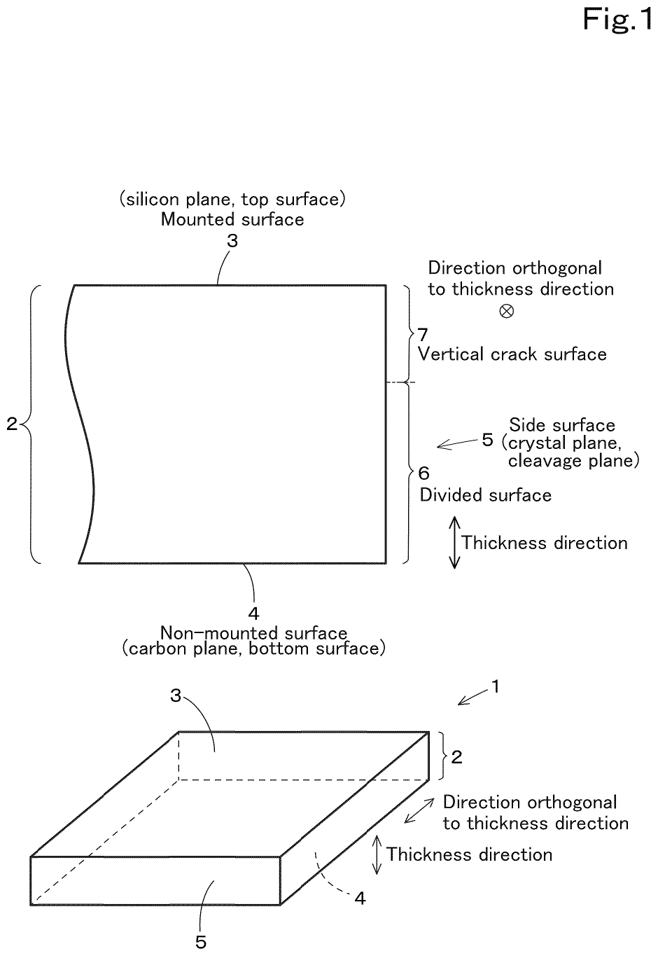

FIG. 1 schematically shows the SiC semiconductor device 1 (chip 1) of the first preferred embodiment according to the present invention.

The chip 1 includes a SiC semiconductor layer 2. The SiC semiconductor layer 2 is composed of 4H-SiC single crystal. The SiC semiconductor layer 2 is diced into and shaped as a plurality of chips serving as a plurality of substrates of the chips 1. The SiC semiconductor layer 2 has a first main surface 3 (mounted surface or top surface) on one hand, a second main surface 4 (non-mounted surface or bottom surface) on the other hand, and four side surfaces 5A, 5B, 5C and 5D that connect the first main surface 3 to the second main surface 4.

The first main surface 3 is formed into a quadrangular shape (a square shape in the present embodiment) in a plan view. The second main surface 4 is also formed into the same square shape as the first main surface 3. The first main surface 3 is the {0001} plane (silicon plane) of the SiC single crystal. The second main surface 4 is the {0001} plane (carbon plane) of the SiC single crystal.

The first main surface 3 is an element-formed surface (mounted surface) on which an element is mounted. The second main surface 4 is a surface (non-mounted surface) to be fixed on a supporting member for the chip 1. When the chip 1 is mounted on the supporting member, the SiC semiconductor layer 2 is placed with the second main surface (non-mounted surface) 4 facing the supporting member.

Each one of the four side surfaces 5 is in a crystal plane (cleavage plane) of the SiC single crystal. The crystal planes (cleavage planes) are exposed on the side surfaces 5 of the chip 1, preserving the crystal structure of the SiC semiconductor layer 2 to enhance the bending strength, thereby improving the reliability thereof.

The amount (area ratio) of an area having crystal defects detected over each of the side surfaces 5 of the SiC semiconductor layer (referred to simply as “a crystal defect-generated area” herein) is 10% or less, and preferably 5% or less. When the amount of the crystal defect-generated area on the side surfaces 5 exceeds a predetermined value, a current leakage is likely caused from a starting point at the crystal defect.

In a middle portion of each one of the side surfaces 5 along a thickness direction of the SiC semiconductor layer 2 (middle portion of the side surfaces in the thickness direction), the surface roughness “maximum height Rz [vertical direction]” in the thickness direction of the SiC semiconductor layer 2 and the surface roughness “maximum height Rz [horizontal direction]” in a direction orthogonal to the thickness direction of the SiC semiconductor layer 2 (a direction along a planar direction) are each 5 μm or less. Specifically, the surface roughness “maximum height Rz” of the side surface 5 of the SiC semiconductor layer 2 of the chip 1 is an indicator indicating the presence of the crystal defects that cause the current leakage.

As shown in FIG. 1, the “thickness direction of the SiC semiconductor layer 2” is the vertical direction along the side surface 5 in the figure. The “direction orthogonal to the thickness direction of the SiC semiconductor layer 2” is the depth direction (front-back direction) or the width direction (left-right direction) along the side surface 5 in the figure.

The surface roughness on the side surface 5 in the direction orthogonal to the thickness direction of the SiC semiconductor layer 2 (the direction along the planar direction), i.e., “arithmetic mean roughness Ra [horizontal direction]” is equal to or more than the surface roughness on the side surface 5 in the thickness direction of the SiC semiconductor layer 2, i.e., “arithmetic mean roughness Ra [vertical direction]”, satisfying the following formula [1]. In particular, the surface roughness in the thickness direction of the SiC semiconductor layer 2 affects the current leakage of the chip 1.

Ra [horizontal direction]≥Ra [vertical direction] [1]

The chip 1 is obtained by forming scribe lines L on the wafer 11 using a scribing tool (such as a scribing wheel) and then applying an external force along the scribe lines L to divide the wafer 11.

Specifically, a scribing apparatus for forming the scribe lines and a breaking apparatus for applying an external force along the scribe lines are used to divide the wafer 11 for producing the chip 1 having cleavage planes 5 (crystal planes of the SiC single crystal).

A technique for producing a plurality of chips 1 by forming scribe lines L in the wafer 11 and then breaking the wafer 11 along the scribe lines L is referred to as a Scribing and Breaking technique (or simply SnB technique) (cf. FIG. 9).

For example, the scribe lines L may be formed by rolling the cutting edge of the scribing wheel (a peripheral sharp edge of the disk-shaped scribing wheel) on the wafer 11 with the cutting edge pressed on the wafer 11. Besides the scribing wheel, a stationary blade (such as a diamond-point cutter) may alternatively be used to form the scribe lines L.

The cleavage planes 5 are smooth surfaces having no crystal defects and irregularities thereon, but surfaces other than the cleavage planes likely have crystal defects and irregularities thereon. Thus, the chips are diced by the blade dicing technique, resulting in the divided side surfaces of the chips different from the cleavage planes, which causes more crystal defects and irregularities than those with the SnB technique.

With the SnB technique, the scribing wheel is used to form scribe lines L in the wafer 11, which is divided along the scribe lines L to dice the wafer into a plurality of the chips 1. Thus, the SnB technique causes vertical cracks on the scribe lines L to extend along the cleavage planes, adapting cleavability (cleavage planes) of the SiC single crystal, to divide the wafer 11 into a plurality of the chips 1 having the side surfaces 5 of the chips 1 along the cleavage planes. This achieves remarkable advantages in reducing the current leakage and enhancing the strength on the chips 1.

Apparatuses used to produce a plurality of the chips 1 from the wafer 11 include a scribing apparatus for forming scribe lines L on the wafer 11 and a breaking apparatus for dividing the wafer 11 along the scribe lines L to produce a plurality of the chips 1. The scribing apparatus and the breaking apparatus may be combined as an integrated apparatus.

The scribing apparatus includes a table on which the wafer 11 is seated, a scribing head for forming a plurality of scribe lines L (vertical cracks) on the main surface of the wafer 11, and a scribing beam on which the scribing head etc. are disposed. Generally, the scribe lines L extend in the X-axis direction of the wafer 11 (the width direction, the direction of the scribing beam) and the Y-axis direction orthogonal to the X-axis direction (the feeding direction, which is perpendicular to the scribing beam direction).

The scribing head is operable to be driven by a motor in the X-axis direction (the width direction of the wafer 11) along a guidance of the scribing beam having a gate-shaped intensity or a flat-top profile distribution intensity. The scribing apparatus may include a plurality of scribing heads (a first scribing head and a second scribing head).

The first scribing head includes a first scribing tool which is used to form scribe lines L1 in the X-axis direction on the wafer 11 while moving in the X-axis direction along the scribing beam. The second scribing head includes a second scribing tool for forming scribe lines L2 in the Y-axis direction on the wafer 11 seated on a table which is driven in the Y-axis direction relative to the second scribing tool. Each of the first and second scribing heads is movable in the Z-axis direction.

The breaking apparatus includes a breaking bar (blade) which is pressed along the scribe lines L onto one of the main surfaces of the wafer 11 opposite to another one of the main surfaces having the scribe lines L formed thereon to divide or separate the wafer 11 into a plurality of substrates (chips 1).

The breaking apparatus includes a braking table for the wafer 11 to be seated and divided, a breaking unit suspended over the table, and a beam oscillator irradiating to the table, a guidance beam having a gate-shaped intensity or a flat-top profile distribution intensity. The breaking unit includes a first breaking unit for dividing the wafer 11 along the scribe lines L1 in the X-axis direction and a second breaking unit for dividing the wafer 11 along the scribe lines L2 in the Y-axis direction. The breaking bars (blades) for dividing the wafer 11 along the scribe lines L1 and L2 are disposed at the distal edges (lower edges) of the first and second breaking units. Each of the breaking units are operable to move upward and downward in the Z-axis direction along the beam by means of an elevating mechanism.

The structures of the scribing apparatus and the breaking apparatus are not limited to those as described above.

For example, the scribing apparatus may include a rotating mechanism for rotating a fitting member (holder) for fitting the scribing tool of the first scribing head around the Z-axis, or alternatively for rotating the table for the wafer to be seated around the Z-axis, to form the first scribe lines L1 in the X-axis direction and the second scribe lines L2 in the Y-axis direction by means of the scribing tool of the first scribing head upon rotation of the rotating mechanism around the Z-axis. This eliminates necessity of the second scribing head.

Also, the breaking apparatus may include another rotating mechanism for rotating the wafer 11 or the table for the wafer 11 to be seated around the Z-axis, to divide the wafer along the scribe lines L1 in the X-axis direction and along the scribe lines L2 in the Y-axis direction. This eliminates necessity of the second breaking unit.

Instead of the braking table, a second blade below the wafer 11 may be used together with the first blade opposed to the second blade, to support the wafer 11 on and apply a pressing or nipping force to the main surfaces 13, 14, thereby dividing the wafer 11 into a plurality of substrates (chips 1).

Each of the side surfaces 5 of the SiC semiconductor layer 2 includes vertical crack surface 7 originating from vertical cracks generated during formation of the scribe lines L and divided surface 6 formed when an external force is applied along the scribe lines L to divide the wafer.

Specifically, when the scribing tool is used to form the scribe lines L on the wafer 11, the cracks extend straight in the depth direction, so that vertical cracks with a given depth are formed. The extended cracks define the “vertical crack surfaces 7” on the side surface 5 of each of the chips 1 after dividing the SiC semiconductor layer 2 into a plurality of the chips 1.

When the breaking bar is pressed onto the wafer 11 to divide the wafer 11, the wafer 11 is cleaved with the vertical cracks as the starting points because of the cleavability of the SiC crystal material, thereby to expose smooth surfaces. The smooth surfaces are in the cleavage planes (crystal planes of the SiC single crystal) and define the “divided surfaces 6” on the side surfaces 5 of each of the chips 1 after dividing the SiC semiconductor layer 2 into a plurality of the chips 1.

On each of the side surfaces 5 of the SiC semiconductor layer 2, the vertical crack surface 7 may be formed adjacent to or closer to the mounted surface 3 and divided surface 6 may be formed adjacent to or closer to non-mounted surface 4, or alternatively the divided surface 6 may be formed adjacent to or closer to the mounted surface 3 and vertical crack surface 7 may be formed adjacent to or closer to non-mounted surface 4.

The thickness (depth) of the vertical crack surfaces 7 in the thickness direction of the SiC semiconductor layer 2 is 30% or less of the thickness of the SiC semiconductor layer 2, and in a range between preferably 1% to 30%, more preferably 5% to 20%, and particularly preferably 5% to 15%.

The vertical crack surfaces 7 of excessive depth unlikely forms the desired cleavage planes 5.

The surface roughness on the vertical crack surface 7 in the direction orthogonal to the thickness direction (the direction along the planar direction), i.e., “arithmetic mean roughness Ra [vertical crack surface, horizontal direction]” is equal to or less than the surface roughness on the divided surface 6 in the direction orthogonal to the thickness direction (the direction along the planar direction), i.e., “arithmetic mean roughness Ra [divided surface, horizontal direction]”, satisfying a following formula [2].

$$Ra [ vertical crack surface , horizontal direction ] \leq Ra [ divided surface , horizontal direction ] \qquad [ 2 ]$$

Thus, according to the present embodiment, when the wafer 11 is divided using the scribing apparatus and the breaking apparatus (SnB), thanks to the vertical crack surfaces formed by scribing and the divided surfaces formed by breaking the semiconductor layer 2, the side surfaces 5 of the chips 1 include the smooth cleavage planes 5 (crystal planes of the SiC single crystal) exposed due to cleavability of the SiC crystal material so as to preserve the crystal structure on the side surfaces 5, thereby reducing crystal defects thereon. In this context, it is desirable to design scribing conditions or the like such that the vertical crack surfaces 7 have the surface roughness less than the divided surfaces 6.

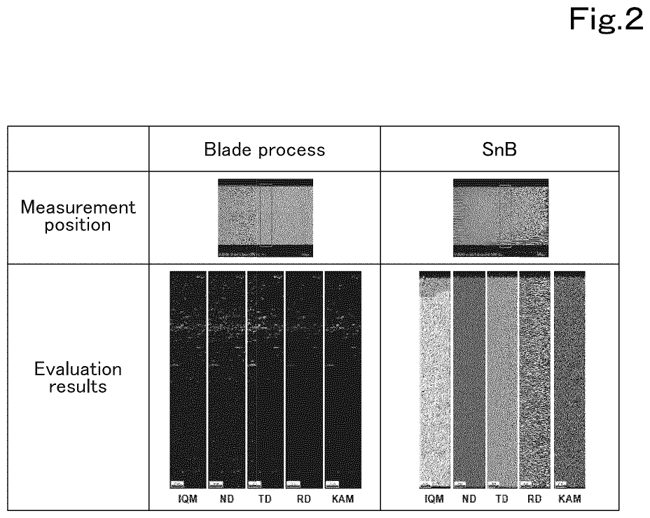

FIG. 2 shows the analysis results on the crystal plane of the SiC semiconductor device (chip 1) obtained by dividing a wafer 11 (blade dicing, Comparative Example) and the analysis results on the crystal plane 5 of the chip 1 of the present invention (SnB, Inventive Example).

In those analysis results, the EBSD (Electron Back Scattered Diffraction Pattern) technique was used to analyze the SiC semiconductor layer 2 of the chip 1.

In comparison of the analysis results between Comparative Example and Inventive Example shown in FIG. 2, an IQM (Image Quality Map or IQ value map) indicates that the image on the chip 1 of the present invention is more uniform, which proves the side surfaces 5 having the smoother surfaces and higher crystallinity (see, the right images in FIG. 2).

Each of ND, TD, RD and KAM images on the chip 1 of the present invention are more uniform (gray, even), which indicate the analysis results proving that the chip 1 of the present invention has a better property regarding crystal orientation, strain and stress (see the right images in FIG. 2).

In the right images in FIG. 2, the color (gray) scales in the images are used for easy understanding of the analysis results for the IQM, ND, TD, RD and KAM.

Contrary, regarding the SiC semiconductor device (chip) obtained by dividing the wafer 11 by blade dicing, a plurality of fine spots (such as white spots) are found in black images, and the divided surface cannot be recognized as an image. Specifically, the analysis results show that the crystallinity is poor (see the left images in FIG. 2).

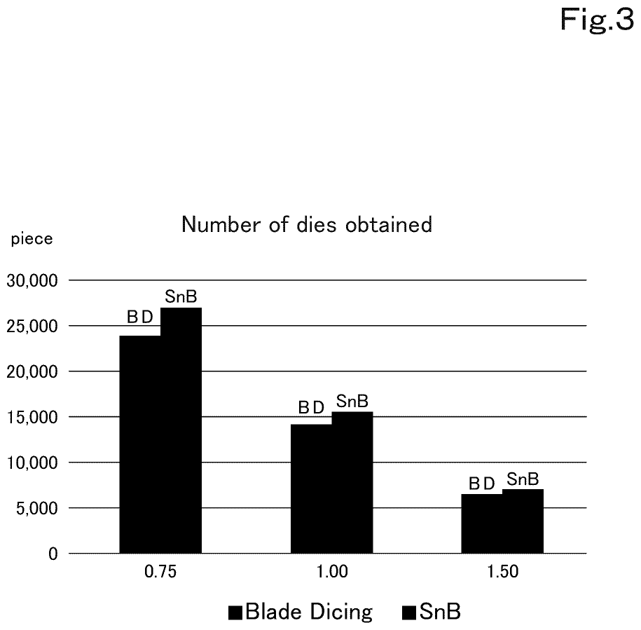

FIG. 3 shows the comparison of the number of SiC semiconductor devices (chips) 1 obtained.

As shown in FIG. 3, the SnB (Scribing and Breaking) process according to the present invention includes a scribing step followed by a breaking (dividing) step so as to increase the number (yield) of chips 1 produced from a single semiconductor wafer relative to the conventional blade dicing process. Specifically, a larger number of chips 1 can be produced from a single semiconductor wafer 11. The blade dicing process requires a cutting allowance equal to or larger than the width of the dicing blade. However, the SnB process is not a removal process and requires less or no cutting allowance, which achieves the increased number of chips produced from a single semiconductor wafer 11.

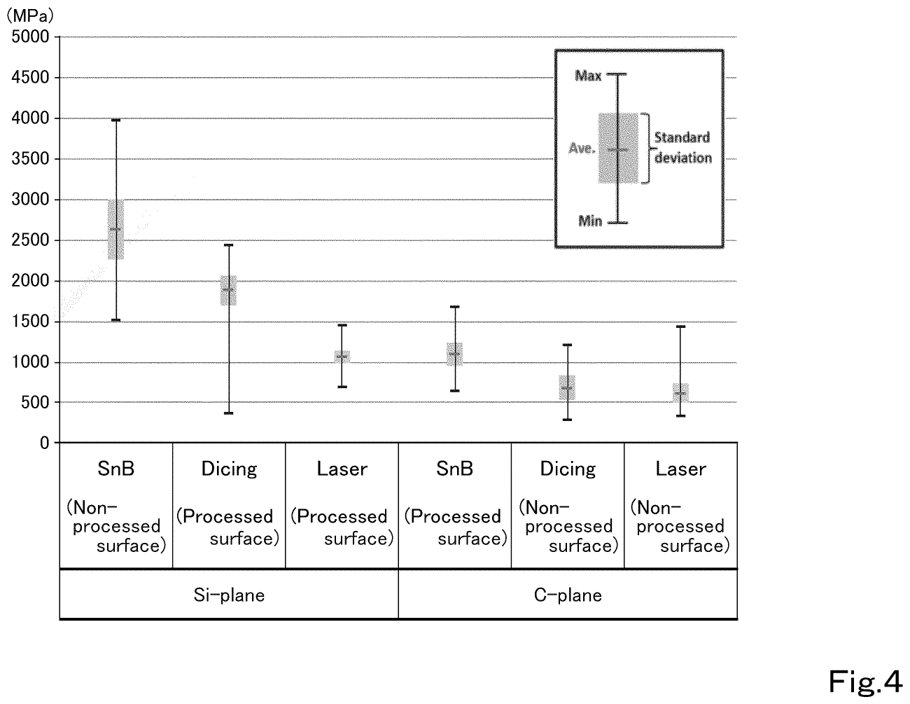

FIG. 4 shows the comparison of the bending strengths of chips 1.

As clearly understood from FIG. 4, the SnB process according to the present invention including the scribing step followed by the breaking (dividing) step can preserve the crystal structure of the side surfaces (divided surfaces) 5 to enhance the bending strength of the chip 1, when compared with the conventional blade-dicing process and the laser-cutting process.

According to the present invention, the SiC semiconductor device 1 can be realized which reduces the crystal defects to suppress the current leakage on the side surfaces 5 due to the crystal defects, thereby to improve the reliability of the SiC semiconductor device 1. Moreover, according to the present invention, the crystal defects can be reduced, which narrows an area of a region (a peripheral voltage withstanding region, a depletion layer) for isolating crystal defects on the side surfaces 5 from the element-formed region on the first wafer main surface 13, thereby to reduce the size of the SiC semiconductor device 1.

### Second Embodiment

In a case where the chips 1 are produced from a wafer 11 of a 4H-SiC single crystal (with an off-angle of 4°), the chips 1 may be configured as follows.

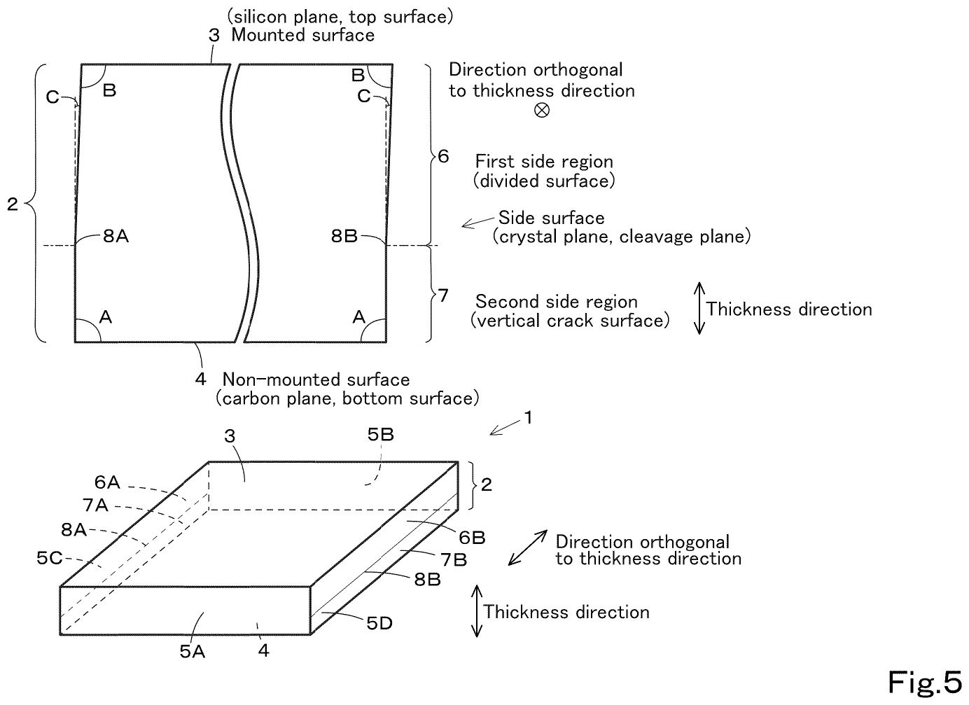

FIG. 5 schematically shows an example of the chip 1 produced from the wafer 11 of the 4H-SiC single crystal (with an off-angle of 4°) according to the second embodiment of the present invention.

As shown in FIG. 5, the thickness direction of the SiC semiconductor layer 2 is the vertical direction along the side surface 5 in the figure. The direction orthogonal to the thickness direction of the SiC semiconductor layer 2 is the depth direction (front-back direction) or the width direction (left-right direction) along the side surface 5 in the figure.

As shown in FIG. 5, the chip 1 according to the present embodiment includes the SiC semiconductor layer 2. The SiC semiconductor layer 2 is composed of 4H-SiC single crystal. The SiC semiconductor layer 2 is diced into and shaped as a plurality of chips serving as a plurality of substrates of the chips 1. The SiC semiconductor layer 2 has a first main surface 3 (mounted surface or top surface) on one hand, a second main surface 4 (non-mounted surface or bottom surface) on the other hand, and four side surfaces 5A, 5B, 5C and 5D that connect the first main surface 3 to the second main surface 4.

Among the side surfaces 5, a first pair of side surfaces 5A and 5B are opposing to each other, each of which is in the crystal plane of the SiC single crystal. Specifically, each of the side surfaces 5A and 5B is in the cleavage plane of the SiC single crystal.

A second pair of side surfaces 5C and 5D are opposing to each other, each of which has a first side region 6 (divided surface 6) adjacent to the mounted surface 3 or the non-mounted surface 4 and a second side region 7 (vertical crack surface 7) adjacent to the non-mounted surface 4 or the mounted surface 3, in which the first side region 6 is inclined to the second side region 7 by a predetermined angle. The first side region 6 is in the crystal plane of the SiC single crystal. The second side region 7 is also the crystal plane. The crystal plane of the first side region 6 is a better crystal plane than the crystal plane of the second side region 7.

Preferably, the angle A between the second side region 7 (vertical crack surface 7) and the non-mounted surface 4 or the mounted surface 3 is closer to 90° than the angle B between the first side region 6 (divided surface 6) and the mounted surface 3 or the non-mounted surface 4. Specifically, it is preferable that the second side region 7 (vertical crack surface 7) has a surface extending in the vertical direction with respect to the non-mounted surface 4 or the mounted surface 3.

It is desirable to design the first side region 6 and the second side region 7 so that the angle A [°] between the second side region 7 and the non-mounted surface 4 or the mounted surface 3 and the angle B [°] between the first side region 6 and the mounted surface 3 or the non-mounted surface 4 satisfy the following formula [3].

$$Absolute value of ( 90 ° - angle B [ ° ] ) > Absolute value of ( 90 ° - angle A [ ° ] ) \qquad [ 3 ]$$

In other words, the direction of the second side region 7 (the vertical crack surface 7) with respect to the non-mounted surface 4 or the mounted surface 3 is closer to the vertical direction than the direction of the first side region 6 (the divided surface 6) with respect to the mounted surface 3 or the non-mounted surface 4.

Even in a case where the chips 1 are produced from a wafer 11 of an off-angle 4H-SiC single crystal of a brittle crystalline material, the divided surfaces 5 of the semiconductor device 1 are exposed in the crystal planes (cleavage planes) to preserve the crystal structure on the side surfaces 5, thereby enhancing bending strength and reliability of the SiC semiconductor chips 1.

One of the second pair of side surfaces 5C, 5D includes a ridge line 8A where the first side region 6A meets the second side region 7A, and another one of the second pair of side surfaces 5C, 5D includes a valley line 8B where the first side region 6A meets the second side region 6B.

Specifically, due to the cleavability of the SiC crystal material, the ridge line 8A is formed on a convex line, and the valley line 8B is formed on the concave line.

The angle C between the first side region 6 (divided surface 6) and the second side region 7 (vertical crack surface 7) is within the range of 0.1 to 10°. The side surface, which includes the valley line 8B between the first side region 6 and the second side region 7, is inclined to the main surface (adjacent to the mounted surface or the non-mounted surface) by an acute or sharp angle which is more likely damaged as the angle C is excessively larger.

The angle A between the second side region 7 (vertical crack surface 7) and the non-mounted surface 4 or the mounted surface 3 is within the range of 85° to 95°. In this case, when the angle A is small, the edge of the second side region 7 forms an acute angle, protrudes, and therefore is easily broken. For example, when the 4H-SiC single crystal (with an off-angle of 4°) is used for producing the chips 1, the angle A is within the range of 87 to 93°.

This is applicable to a 2H-SiC single crystal (with an off-angle of 2°), a 6H-SiC single crystal (with an off-angle of 6°) or the like. For example, when a 2H-SiC single crystal is used for producing the chips 1, the angle A is within the range of 89 to 91°. When a 6H-SiC single crystal is used for producing the chips 1, the angle A is within the range of 85 to 95°.

The first side region 6 (divided surface 6, cleavage plane) corresponds to the {11-20} plane ((11-20) plane or (-1-120) plane) of the SiC single crystal. By utilizing the cleavability of the SiC crystal material, a large area of the smooth crystal planes described above (the planes on which the current leakage can be suppressed) can be exposed.

The chips 1 are produced by forming a plurality of scribe lines L on the SiC semiconductor wafer 11 using a scribing tool (such as a scribing wheel) and then applying an external force along the scribe lines L to divide the SiC semiconductor wafer 11.

Specifically, according to the present invention, the SiC semiconductor wafer 11, which is a brittle crystalline SiC material, is divided using a scribing apparatus and a breaking apparatus, thereby to produce a plurality of chips 1 each having cleavage planes 5 (crystal planes of the SiC single crystal).

The cleavage planes 5 are smooth surfaces, and crystal defects or the like are not formed thereon. However, crystal defects and irregularities or the like are formed on surfaces other than the cleavage planes. A processing method such as the blade dicing has a problem because the divided surfaces of the chips are surfaces different from cleavage planes.

As described above, the inventors have confirmed, taking the cleavability of the SiC single crystal into consideration, that the chips 1 are preferably obtained by forming a plurality of scribe lines on the wafer 11 using a scribing tool and then applying an external force along the plurality of scribe lines to divide the SiC semiconductor wafer 11. This forms the divided surfaces of the side surface 5 along the cleavage plane (crystal plane of the SiC single crystal), thereby preventing the current leakage and improving the strength thereof. Specific examples of the scribing apparatus and the breaking apparatus are substantially the same as those in the first embodiment, and their detailed description is omitted.

The second side region 7 is named as the “vertical crack surface 7” originating from the vertical crack generated by forming the plurality of scribe lines L. The first side region 6 is named as the “divided surface 6” formed by applying the external force along the plurality of scribe lines to divide the wafer.

Specifically, when the scribing tool is used to form the scribe lines L on the wafer 11, the cracks extend straight in the depth direction, so that vertical cracks with a given depth are formed. These cracks serve as the starting points for breaking the wafer 11, and the “vertical crack surface 7” that forms the second side region 7 on each side surface 5 is thereby formed.

When the breaking bar is pressed onto the wafer 11 during breaking, the wafer 11 is cleaved with the cracks serving as the starting points due to the cleavability of the SiC crystal material, and smooth surfaces are exposed. In this manner, the smooth “divided surface 6” is formed or defined on the first side region 6 of each side surface 5 due to the cleavability of the SiC crystal material. This divided surface 6 is a cleavage plane (a crystal plane of the SiC single crystal).

The first side region 6 (divided surface 6) may be formed on the side surface 5 adjacent to the mounted surface 3, and the second side region 7 (vertical crack surface 7) may be formed on the side surface 5 adjacent to the non-mounted surface 4. Alternatively, the first side region 6 (divided surface 6) may be formed on the side surface 5 adjacent to the non-mounted surface 4, and the second side region 7 (vertical crack surface 7) may be formed on the side surface 5 adjacent to the mounted surface 3.

The thickness (depth) of the second side region 7 (vertical crack surface 7) in the thickness direction of the SiC semiconductor layer 2 is 30% or less of the thickness of the SiC semiconductor layer 2 and is within the range of preferably 1 to 30%, more preferably 5 to 20%, and particularly preferably 5 to 15%. If the vertical cracks are not generated, it is difficult to divide the wafer 11 to obtain the chips 1. If vertical cracks with a larger depth than the above depth are formed, the wafer 11 undergoes surface fracture (horizontal cracking, peeling).

Specifically, according to the present embodiment, the SiC semiconductor wafer 11 is divided using the scribing apparatus and the breaking apparatus. Then the vertical cracks formed during scribing and the cleavability of the SiC crystal material during breaking allow the smooth cleavage planes 5 (crystal planes 5 of the SiC single crystal) to be exposed on the divided surfaces of the chips 1. In this manner, a wafer even with an off-angle of 4°, for example, can also be divided along the cleavage planes 5. Moreover, the crystal defects can be reduced, and the crystal structure of the divided surfaces of the chips 1 can be maintained.

According to the present embodiment, chipping can be controlled, so that the bending strength of the chips 1 can be improved. In this manner, the reliability of the chips 1 can be improved.

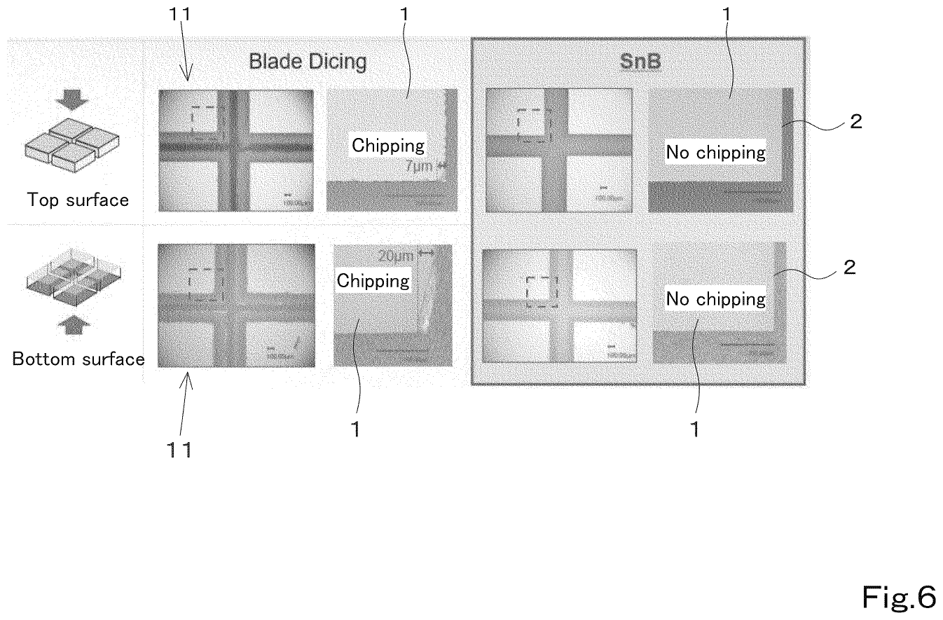

FIG. 6 shows images comparing the presence or absence of chipping determined by observing edges of SiC semiconductor devices (chips) divided by blade dicing (Comparative Example) and edges of the chips 1 of the invention (Inventive Example).

As shown in FIG. 6, since the conventional blade dicing process scrapes or digs the wafer 11, chipping, microcracking, or the like at the edges of the chips 1 is inevitable (see the left images in FIG. 6).

However, the processing process (SnB: Scribing and Breaking) according to the present invention, the wafer 11 is scribed and then broken or divided into the chips 2 by selecting the processing conditions, which causes no chipping formed at the edges of the chips 1, thereby to keep the chips in a good condition (see the right images in FIG. 6).

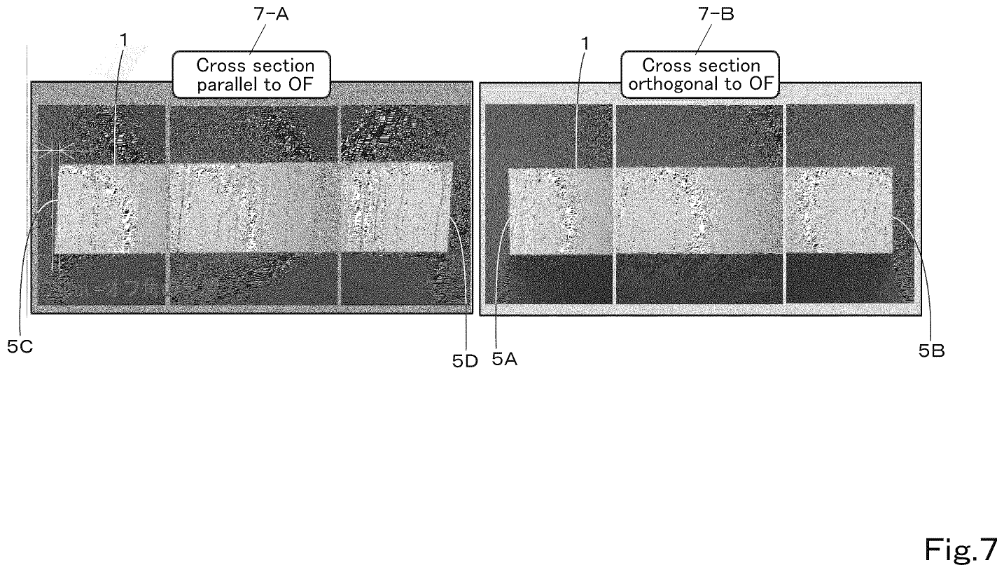

FIG. 7 compares an observed image of a cross section taken in a direction parallel to the orientation flat (OF) 16 with another observed image of a cross section taken in a direction perpendicular to the orientation flat (OF) 16.

As can be seen in FIG. 7, the opposed side surfaces 5C, 5D orthogonal to the cross section parallel to the orientation flat 16 have slightly inclined surfaces due to the cleavability of the SiC crystal material (the 4H-SiC single crystal having the off-angle of 4°) (25 μm=the influence of the off-angle). On the other hand, the opposed side surfaces 5A and 5B orthogonal to the cross section perpendicular to the orientation flat (OF) 16 are vertical surfaces.

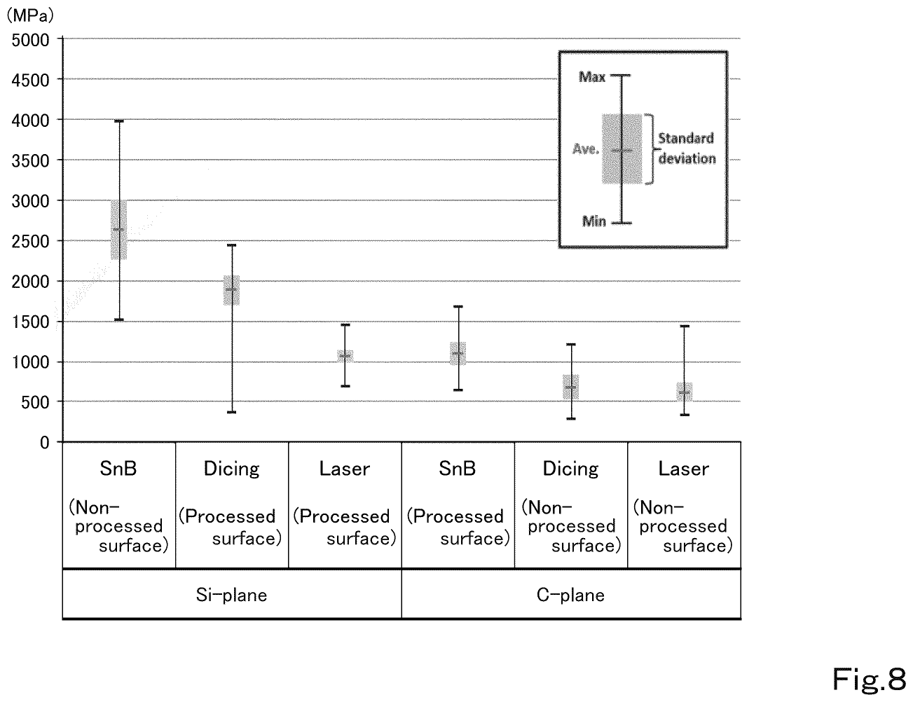

FIG. 8 compares the bending strengths of the SiC semiconductor devices (chips) 1.

As can be seen in FIG. 8, according to the present invention, since the crystal structure of the divided surfaces of the chips 1 is preserved, the bending strength is high.

As described above, the chip 1 according to the invention is produced by dividing the wafer 11 by means of the process adapting the cleavability of the crystalline material, in which the wafer 11 is scribed and then broken or divided into the chips 2, specifically by selecting (optimizing) the process conditions during division, such as specifications of the scribing tool (the outer diameter of a scribing wheel, the angle of its cutting edge, micromachining on the cutting edge, or the like), a scribing load, a scanning speed of the scribing tool, specifications of a breaking bar (the angle of its cutting edge and a tip shape of the cutting edge), a gap between receiving blades, a hardness of a table, a breaking load (pressing amount), and a pressing down speed of the breaking bar), the wafer can be preferentially divided along the cleavage directions even when the wafer 11 has the off-angle, and the divided surfaces 6 of the chips 1 can be formed to expose the crystal planes (cleavage planes) thereon.

By selecting the processing conditions during division as described above, chipping and microcracking that may occur when the wafer 11 is divided can be controlled. By causing crystal planes (cleavage planes) to be exposed on the side surface 5 of the chip 1, the bending strength of the chip 1 is improved. The reliability of the chip 1 can thereby be improved.

Specifically, in the chip 1 of the invention, even when the wafer 11 formed of a brittle crystalline material has an off-angle (for example, a 4H-SiC single crystal (with an off-angle of 4°) is used), crystal planes are caused to be exposed on the side surface 5 such as the first side region 6 and the second side region 7 of the semiconductor device 1 in consideration of the cleavability during division. In this manner, the crystal structure can be preserved without generation of crystal defects on the side surface 5, and chipping and microcracking can be controlled. The bending strength is thereby increased, and the reliability can be improved.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A SiC semiconductor device including a SiC semiconductor layer composed of SiC single crystal, the SiC semiconductor layer comprising:
a mounted surface on which an element is mounted;
a non-mounted surface opposed to the mounted surface; and
a side surface connecting the mounted surface to the non-mounted surface, wherein
the side surface is on a cleavage plane of the SiC single crystal.

2. The SiC semiconductor device according to claim 1, wherein
the amount (area ratio) of an area having crystal defects detected over the side surface of the SiC semiconductor layer by means of an EBSD (Electron Backscatter Diffraction Pattern) analysis is 10% or less.

3. The SiC semiconductor device according to claim 1, wherein
in a middle portion of the side surface along a thickness direction of the SiC semiconductor layer, each of a vertical surface roughness (maximum height Rz, vertical) along the thickness direction and a horizontal surface roughness (maximum height Rz, horizontal) along a horizontal direction orthogonal to the thickness direction is 5 μm or less.

4. The SiC semiconductor device according to claim 3, wherein
a horizontal arithmetic mean surface roughness (Ra, horizontal) along the horizontal direction is equal to or more than a vertical arithmetic mean surface roughness (Ra, vertical) along the horizontal direction to satisfy following formula [1]:
Ra [horizontal direction]≥Ra [vertical direction]. [1]

5. The SiC semiconductor device according to claim 1, wherein
the SiC semiconductor device is produced by forming a scribe line on a SiC semiconductor wafer using a scribing tool and then applying an external force along the scribe line to divide the SiC semiconductor wafer.

6. The SiC semiconductor device according to claim 5, wherein
the side surface of the SiC semiconductor layer includes a vertical crack surface originating from a vertical crack generated by forming the scribe line, and a divided surface formed by applying the external force along the scribe line to divide the SiC semiconductor layer.

7. The SiC semiconductor device according to claim 6, wherein
on the side surface of the SiC semiconductor layer, the vertical crack surface is adjacent to the mounted surface, and the divided surface is adjacent to the non-mounted surface.

8. The SiC semiconductor device according to claim 6, wherein
on the side surface of the SiC semiconductor layer, the vertical crack surface is adjacent to the non-mounted surface, and the divided surface is adjacent to the mounted surface.

9. The SiC semiconductor device according to claim 6, wherein
a thickness of which the vertical crack surface extends along a thickness direction of the SiC semiconductor layer is 20% or less of a thickness of the SiC semiconductor layer.

10. The SiC semiconductor device according to claim 6, wherein
an arithmetic mean roughness (Ra, vertical crack surface, horizontal) of the vertical crack surface in a direction orthogonal to a thickness direction is equal to or less than an arithmetic mean roughness (Ra, divided surface, horizontal) of the divided surface in the direction orthogonal to the thickness direction to satisfy following formula [2]:
Ra [vertical crack surface, horizontal]≤Ra [divided surface, horizontal]. [2]

11. A SiC semiconductor device containing a SiC semiconductor layer composed of SiC single crystal, the SiC semiconductor layer comprising:
a mounted surface on which an element is mounted;
a non-mounted surface opposed to the mounted surface;
a first pair of side surfaces connecting the mounted surface to the non-mounted surface and opposing to each other, each of the first pair of side surfaces being on a cleavage plane of the SiC single crystal; and
a second pair of side surfaces connecting the mounted surface to the non-mounted surface and opposing to each other, wherein
each of the second pair of side surfaces includes first and second side regions, one of the first and second side regions being adjacent to the mounted surface and another one of the first and second side regions being adjacent to the non-mounted surface, and
the first side region is inclined to the second side region by a predetermined angle.

12. The SiC semiconductor device according to claim 11, wherein
one of the second pair of side surfaces has a ridge line where the first side region meets the second side region, and another one of the second pair of side surfaces has a valley line where the first side region meets the second side region.

13. The SiC semiconductor device according to claim 11, wherein
the predetermined angle (C) between the first side region and the second side region is within the range of 0.1° to 10°.

14. The SiC semiconductor device according to claim 11, wherein
the second side region is inclined by a given angle (A) within the range of 80° to 100°, to either one of the mounted surface or the non-mounted surface which is adjacent to the second side region.

15. The SiC semiconductor device according to claim 11, wherein
the first side region is on a {11-20} plane of the SiC single crystal.

16. The SiC semiconductor device according to claim 11, wherein
the SiC semiconductor device is produced by forming a scribe line on a SiC semiconductor wafer using a scribing tool and then applying an external force along the scribe line to divide the SiC semiconductor wafer.

17. The SiC semiconductor device according to claim 16, wherein
the second side region originates from a vertical crack generated by forming the scribe line, and
the first side region is a divided surface formed by applying the external force along the scribe line to divide the SiC semiconductor wafer.

18. The SiC semiconductor device according to claim 17, wherein
the first side region is adjacent to the mounted surface, and the second side region is adjacent to the non-mounted surface.

19. The SiC semiconductor device according to claim 17, wherein
a thickness of which the second side region extends along a thickness direction of the SiC semiconductor layer is 20% or less of a thickness of the SiC semiconductor layer.

20. The SiC semiconductor device according to claim 11, wherein
an angle (B) between one of the non-mounted surface or the mounted surface and the first side region adjacent to the one of the non-mounted surface or the mounted surface is closer to 90° than another angle (A) between another one of the mounted surface or the non-mounted surface and the second side region adjacent to the another one of the mounted surface or the non-mounted surface.
